(19) United States
(12) Patent Application Publication
(10) Pub. No.: US 2025/0349768 A1
(43) Pub. Date: Nov. 13, 2025

(54) MODULE CONTAINING FAN-OUT WAFER-LEVEL PACKAGING UNIT CONNECTED TO ELECTRONIC BY WIRE BONDING

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/201,940

(22) Filed: May 8, 2025

(30) Foreign Application Priority Data
May 13, 2024 (TW) 113117554

(51) Int. Cl. H01L 23/00

(52) U.S. Cl. CPC H01L 24/05; H01L 24/48; H01L 24/94; H01L 2224/02311; H01L 2224/02379; H01L 2224/04042; H01L 2224/05639; H01L 2224/05647; H01L 2224/48225; H01L 2224/94

(57) ABSTRACT

A module containing a fan-out wafer-level packaging (FOWLP) unit connected to an electronic by wire bonding is provided. The module includes a FOWLP unit, an electronic, at least one first bonding wire, and at least two second bonding wires. The FOWLP unit includes a substrate, at least two dies, a first dielectric layer, a second dielectric layer, a plurality of conductive circuits, an outer protective layer, and a plurality of bonding pads. The conductive circuits are formed by a metal paste filled in first slots of the first dielectric layer and second slots of the second dielectric layer. At least one of the bonding pads is located around a chip area on a second surface of the dies to be electrically connected to the outside. Thereby problems of FOWLP modules available now including higher manufacturing cost and less environmental benefits can be solved.

### CROSS-REFERENCE TO RELATED APPLICATIONS

This non-provisional application claims priority under 35 U.S.C. § 119 (a) on Patent Application No(s). 113117554 filed in Taiwan, R.O.C. on May 13, 2024, the entire contents of which are hereby incorporated by reference.

### BACKGROUND OF THE INVENTION

The present invention relates to a module, especially to a module in which a fan-out wafer level packaging (FOWLP) unit is connected to an electronic by wire bonding.

Packaging technology with features of compact design, high efficiency and reliability is a trend in semiconductor industry. In the semiconductor packaging, Fan-Out Wafer Level Packaging (FOWLP) is a packaging technology available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree, the most critical point is the manufacturing of the respective conductive circuits in the RDL. However, the formation of the respective conductive circuits in the RDL of the FOWLP technology available now is by chemical plating or electroplating. Thus not only cost for material and manufacturing is high, the manufacturing process is also not environmental friendly. In order to provide products with higher performance or more functions, at least two dies are disposed in FOWLP unit and the multi-chip type FOWLP unit is integrated by RDL. At the moment, space required for designing respective conductive circuits in the RDL of the FOWLP unit is increased and manufacturing of the conductive circuits in the RDL becomes more crucial.

Moreover, the FOWLP is integrated by RDL to form a FOWLP unit while being applied to manufacturing of module products. Then the FOWLP unit is connected to an electronic component to form the module. Now cost for materials and manufacturing is increased and manufacturing techniques of conductive circuits in the RDL are more critical.

### SUMMARY OF THE INVENTION

Therefore, it is a primary object of the present invention to provide a module containing a fan-out wafer-level packaging (FOWLP) unit connected to an electronic by wire bonding. The module is composed of a FOWLP unit, an electronic, at least one first bonding wire, and at least two second bonding wires. The FOWLP unit includes a substrate, at least two dies, a first dielectric layer, a second dielectric layer, a plurality of conductive circuits, an outer protective layer, and a plurality of bonding pads. The respective conductive circuits are formed by a metal paste filled in a plurality of first slots of the first dielectric layer and a plurality of second slots of the second dielectric layer. At least one of the bonding pads is located around a chip area on a second surface of the respective dies for electrical connection to the outside. Thereby the problems of the FOWLP technology in the module available now generated during manufacturing of the respective conductive circuits including higher manufacturing cost and less beneficial to environmental benefits can be solved.

In order to achieve the above object, a module containing a fan-out wafer-level packaging (FOWLP) unit connected to an electronic by wire bonding according to the present invention includes a substrate, at least two dies, a first dielectric layer, a second dielectric layer, a plurality of conductive circuits, an outer protective layer, a plurality of bonding pads, an electronic, at least one first bonding wire, and at least two second bonding wires. The substrate is provided with a first surface and a second surface opposite to each other. The dies are cut from the same wafer or different wafers and each of the dies is provided with a first surface and a second surface opposite to each other. The dies are arranged at the second surface of the substrate in parallel and spaced apart from each other. The first surface of the die is fixed on the substrate while the second surface of the die is provided with a plurality of die pads. An area just above the second surface is defined as a chip area. The first dielectric layer is mounted to the second surface of the substrate and the second surface of the dies and provided with a plurality of first slots extending in a horizontal direction. The respective die pads of the dies are exposed through the respective first slots. The second dielectric layer is disposed over the first dielectric layer and provided with a plurality of second slots extending in a horizontal direction. The respective second slots are communicating with the respective first slots. The conductive circuits are formed by a metal paste filled in the first slots and the second slots correspondingly. The respective conductive circuits are electrically connected to the respective die pads of the dies. The outer protective layer is arranged over the second dielectric layer and provided with a plurality of openings. At least two of the openings are located around the chip area on the second surface of the respective dies. The respective conductive circuits are exposed through the respective openings. The respective bonding pads formed in the respective openings of the outer protective layer are metal structures with a certain thickness and electrically connected to the respective conductive circuits. The dies are electrically connected to the outside through the die pads, the conductive circuits, and the bonding pads located around the chip area on the second surface of the dies in turn. Thereby the fan-out wafer-level packaging (FOWLP) unit is formed. The electronic component is provided with a first surface on which the first surface of the substrate is disposed.

The first bonding wire forms a first bonding point and a second bonding point on the bonding pads of the dies by a wire bonding process. Thereby electrical connections are formed between the dies of the FOWLP unit. The second bonding wire forms a third bonding point on the bonding pad around the chip area and a fourth bonding point on the first surface of the electronic by the wire bonding process. Thus the respective dies of the FOWLP unit are electrically connected with the electronic. The first bonding wire and the second bonding wire are formed together by the wire bonding process. A method of manufacturing the present module includes the following steps. Step S1: providing a substrate having a first surface and a second surface opposite to the first surface. Step S2: arranging a plurality of dies cut from the same wafer or different wafers on the second surface of the substrate in parallel and spaced from one another. Each of the dies includes a first surface and a second surface opposite to the first surface. The first surface of the die is arranged at the substrate while the second surface of the die is provided with a plurality of die pads. An area just above the second surface of the die is defined as a chip area. Step S3: paving a first dielectric layer over the substrate and the second surface of the respective dies. Step S4: forming a plurality of first slots extending horizontally on the first dielectric layer and exposing the respective die pads of the respective dies through the respective first slots. Step S5: paving a second dielectric layer over the first dielectric layer. Step S6: forming a plurality of second slots extending horizontally on the second dielectric layer and communicating the second slots with the first slots. Step S7: filling a metal paste into the first slots and the second slots and allowing a level of the metal paste higher than a surface of the second dielectric layer. Step S8: grinding the metal paste with the level higher than the surface of the second dielectric layer to make a surface of the metal paste flush with the surface of the second dielectric layer and form a plurality of conductive circuits. Step S9: covering the second dielectric layer with an outer protective layer. Step S10: forming a plurality of openings on the outer protective layer and at least one of the openings is formed around the chip area on the second surface of the respective dies so that the respective conductive circuits are exposed through the respective openings. Step S11: forming a bonding pad in each of the openings of the outer protective layer. The bonding pads are metal structures with a certain thickness and electrically connected to the conductive circuits. Step S12: performing cutting to form a plurality of fan-out wafer-level packaging (FOWLP) units each of which includes at least two of the dies. Step S13: providing an electronic component which includes a first surface and disposing the first surface of the substrate of one of the FOWLP units on the first surface of the electronic component. Step S14: performing a wire bonding process to make at least one first bonding wire form a first bonding point and a second bonding point on the bonding pads of the dies of the FOWLP unit and make at least two second bonding wires form a third bonding point on the respective bonding pads around the chip area of the FOWLP unit and a fourth bonding point on the electronic component. The dies in the FOWLP unit on the electronic component are electrically connected through the respective first bonding wires. The dies in the FOWLP unit on the electronic component and the electronic component are electrically connected through the respective second bonding wires. Thereby the module is formed.

Preferably, the electronic component is a printed circuit board (PCB).

Preferably, a surface of the bonding pad is flush with a surface of the outer protective layer.

Preferably, the dies are cut from the same wafer or different wafers.

Preferably, a level of the second surface of the dies on the substrate is the same with each other.

Preferably, the substrate includes a silicon (Si) substrate, a glass substrate, and a ceramic substrate.

Preferably, the metal paste includes silver paste, nano-scale silver paste, copper paste, and nano-scale copper paste.

Preferably, the first surface of the die is disposed on the substrate by a die attach film (DAF).

### BRIEF DESCRIPTION OF THE DRAWINGS

FIG. 1 is a side sectional view of a module of an embodiment according to the present invention;

FIG. 2 is a side sectional view showing dies arranged at a substrate of an embodiment according to the present invention;

FIG. 3 is a side sectional view showing a first dielectric layer disposed on a substrate and a second surface of respective dies of an embodiment according to the present invention;

FIG. 4 is a side sectional view showing a second dielectric layer disposed on a first dielectric layer of an embodiment according to the present invention;

FIG. 5 is a side sectional view showing first slots and second slots both filled with metal paste of an embodiment according to the present invention;

FIG. 6 is a side sectional view showing grinding of the metal paste with a level higher than a surface of a second dielectric layer in the embodiment in FIG. 5 according to the present invention;

FIG. 7 is a side sectional view showing formation of a plurality of openings on an outer protective layer of an embodiment according to the present invention;

FIG. 8 is a side sectional view of a fan-out wafer-level packaging (FOWLP) unit of an embodiment according to the present invention.

### DETAILED DESCRIPTION OF THE PREFERRED EMBODIMENT

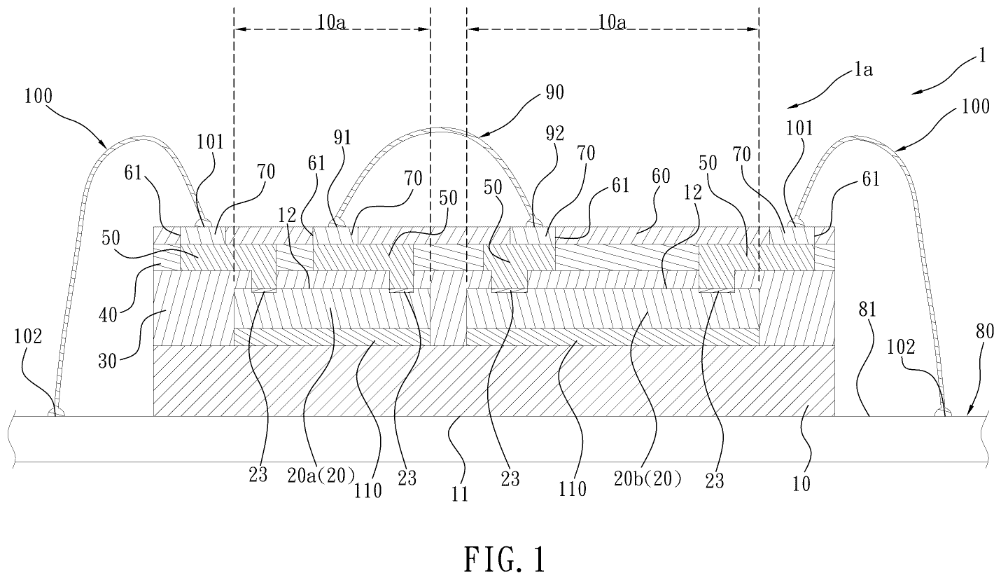

Refer to FIG. 1, a module 1 containing a fan-out wafer-level packaging (FOWLP) unit connected to an electronic by wire bonding according to the present invention is provided. The module 1 includes a fan-out wafer level packaging (FOWLP) unit 1a, an electronic component 80, at least one first bonding wire 90, and at least two second bonding wires 100.

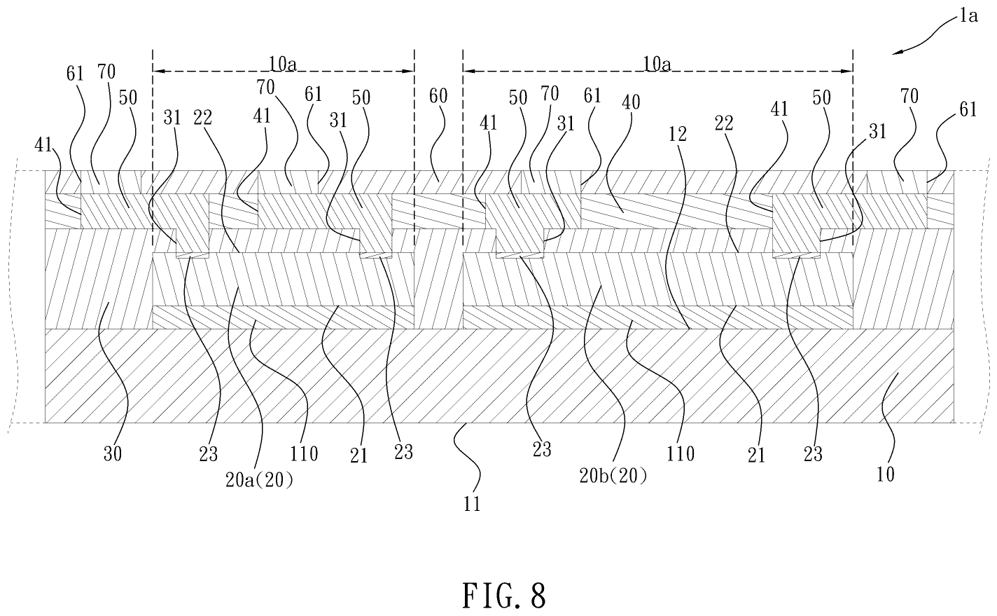

Refer to FIG. 8, the FOWLP unit 1 includes a substrate 10, at least two dies 20, a first dielectric layer 30, a second dielectric layer 40, a plurality of conductive circuits 50, an outer protective layer 60, and a plurality of bonding pads 70.

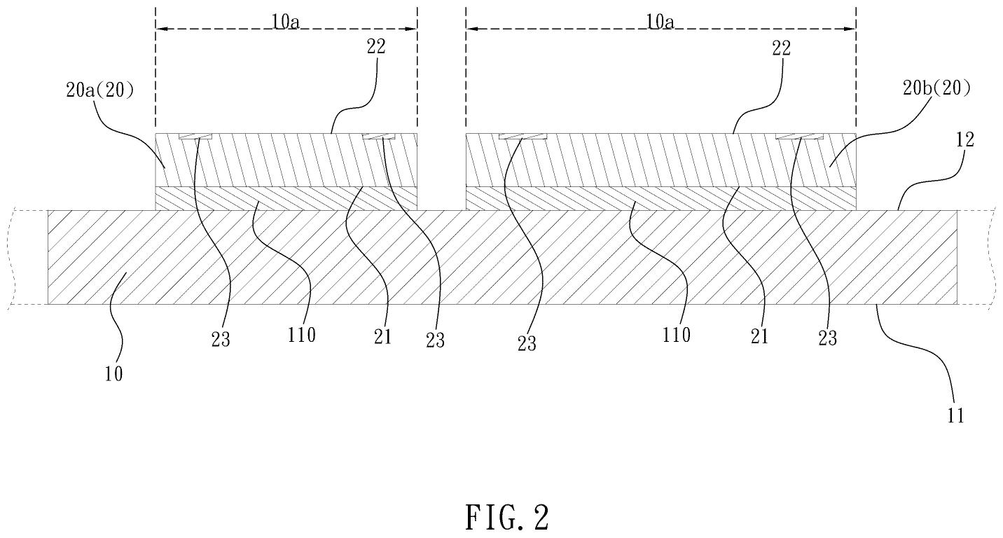

The substrate 10 is provided with a first surface 11 and a second surface 12 opposite to each other, as shown in FIG. 2. The substrate 10 includes a silicon (Si) substrate, a glass substrate, and a ceramic substrate, but not limited. This is beneficial to diversified product development and applications.

The dies 20 are cut from the same wafer or different wafers, arranged at the second surface 12 of the substrate 10 in parallel, and spaced apart from each other, as shown in FIG. 2. Each of the dies 20 is provided with a first surface 21 and a second surface 22 opposite to the first surface 21. The first surface 21 of the die 20 is fixed on the substrate 10 while the second surface 22 of the die 20 is provided with a plurality of die pads 23. An area just above the second surface 22 is defined as a chip area 10a. In FIG. 2, the number of the die pads 23 on the die 20 is two and this is taken as an example, not intended to limit the present invention.

Moreover, in order to explain structures and functions of the present invention, in the embodiments shown in FIG. 1-8, the dies 20 on the substrate 10 further includes a first die 20a and a second die 20b, but not limited. That means two dies 20 are taken as an example, but not intended to limit the present invention.

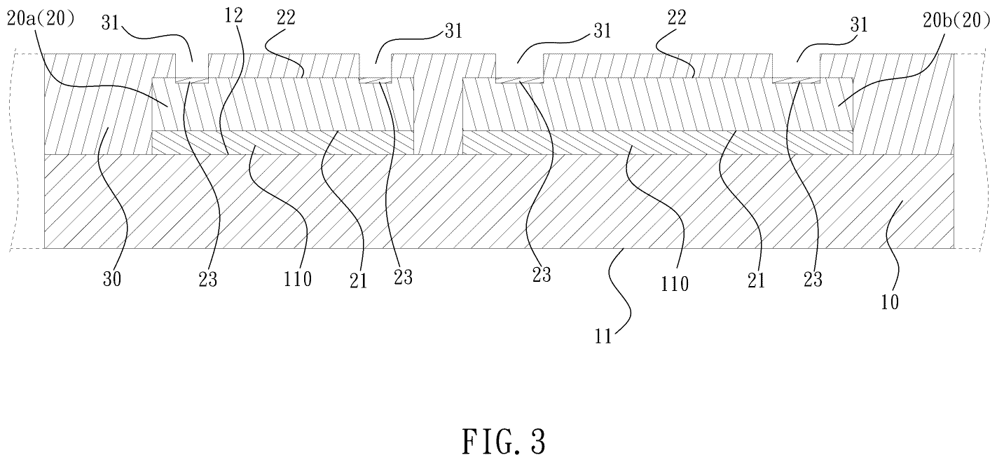

Refer to FIG. 3, the first dielectric layer 30 is mounted to both the second surface 12 of the substrate 10 and the second surface 22 of the dies (20a, 20b) and provided with a plurality of first slots 31 extending in a horizontal direction. The respective die pads 23 of the dies 20 (20a, 20b) are exposed through the respective first slots 31.

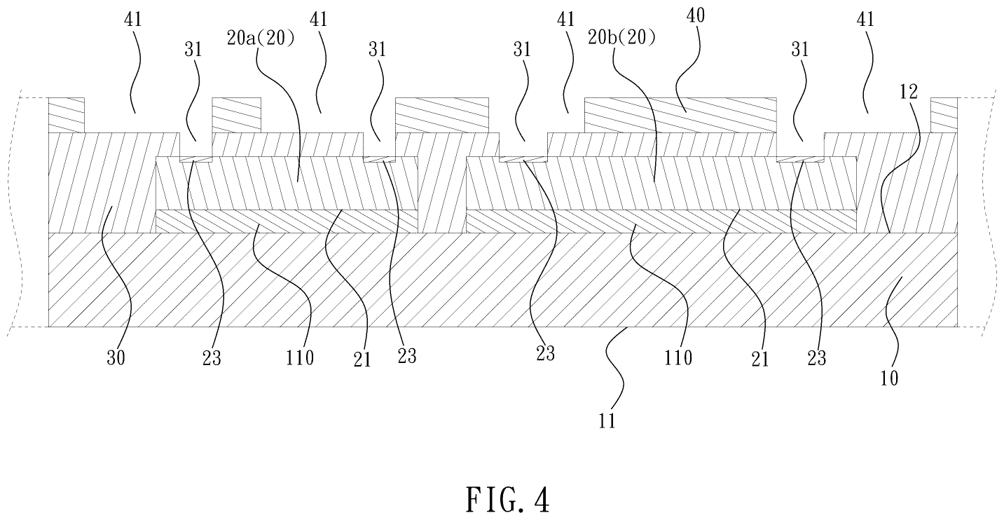

The second dielectric layer 40 is disposed over the first dielectric layer and provided with a plurality of second slots 41 extending in a horizontal direction. The respective second slots 41 are communicating with the respective first slots 31, as shown in FIG. 4.

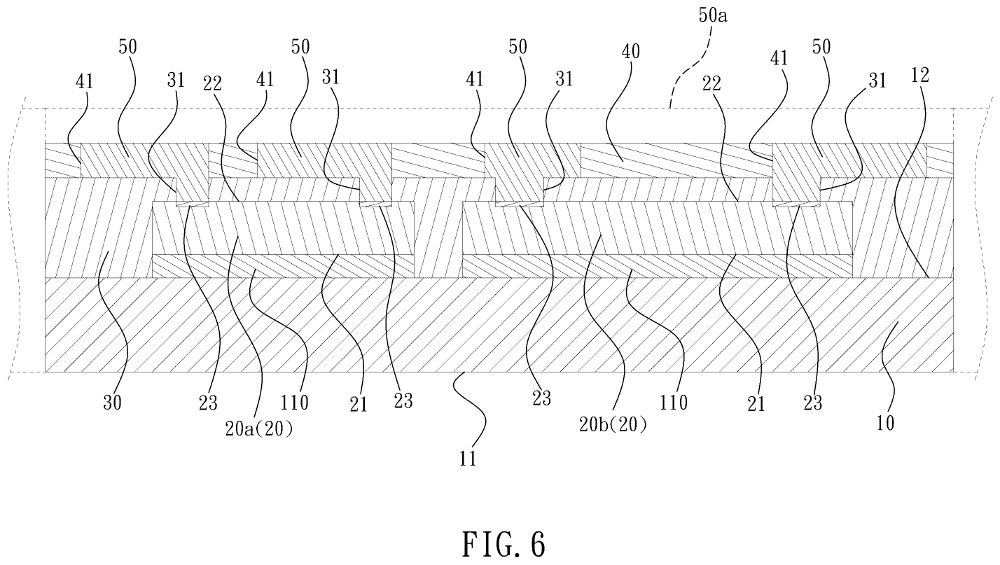

As shown in FIG. 6, the respective conductive circuits 50 are formed by a metal paste 50a filled in the respective first slots 31 and the respective second slots 41. The respective conductive circuits 50 are electrically connected to the respective die pads 23 of the dies 20 (20a, 20b). The metal paste 50a includes, but not limited to silver paste, nano-scale silver paste, copper paste, and nano-scale copper paste.

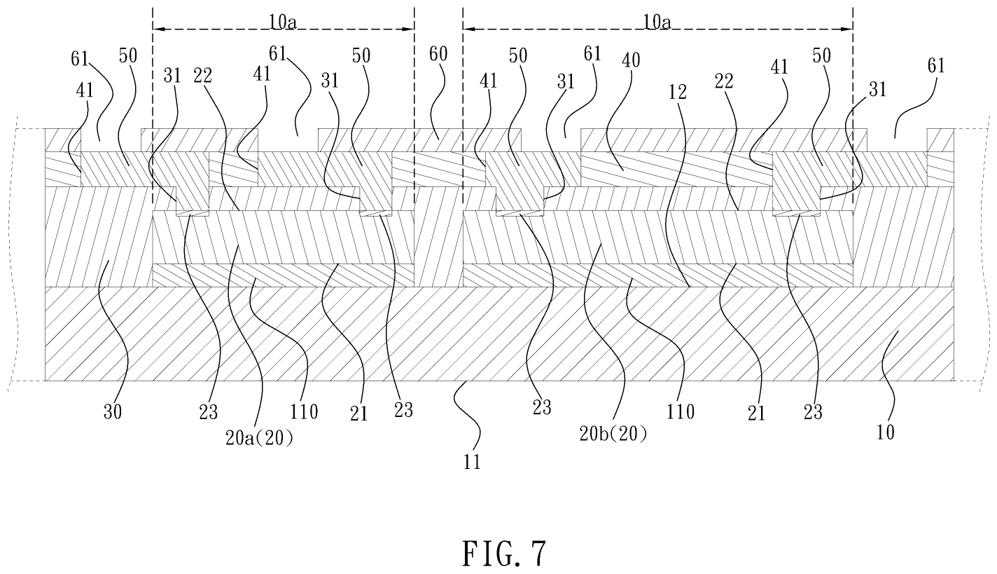

The outer protective layer 60 is arranged over the second dielectric layer 40 and provided with a plurality of openings 61. At least two of the openings 61 are located around the chip area 10a on the second surface 22 of the respective dies 20 (20a, 20b), as shown in FIG. 7. The respective conductive circuits 50 are exposed through the respective openings 61. In FIG. 7, there are four openings 61 in the outer protective layer 60 and this is taken as an example, not intended to limit the present invention.

The respective bonding pads 70 formed in the respective openings 61 of the outer protective layer 60 are metal structures with a certain thickness and electrically connected to the respective conductive circuits 50, as shown in FIG. 8. The respective dies 20 (20a, 20b) are electrically connected to the outside through the respective die pads 23, the respective conductive circuits 50, and the respective bonding pads 70 located around the chip area 10a on the second surface 22 of the respective dies 20 (20a, 20b) in turn. Thereby the fan-out wafer-level packaging (FOWLP) unit 1a is formed, as shown in FIG. 8.

The electronic component 80 is provided with a first surface 81 on which the first surface 11 of the substrate 10 of the FOWLP unit 1a is disposed, as shown in FIG. 1. The electronic component 80 can be a printed circuit board (PCB), but not limited.

The first bonding wire 90 forms a first bonding point 91 and a second bonding point 92 on the respective bonding pads 70 of the dies 20 (20a, 20b) by a wire bonding process. Thereby the dies 20 (20a, 20b) of the FOWLP unit 1a are electrically connected, as shown in FIG. 1.

Furthermore, in order to explain structures and functions of the present invention, in the embodiments shown in FIG. 1, the bonding point on the first die 20a is the first bonding point 91 and the bonding point on the second die 20b is the second bonding point 92. Take one first bonding wire 90 as an example and the first bonding wire 90 is connected to the two adjacent bonding pads 70 on the two dies 20 (20a, 20b) by the wire bonding to form electrical connection between the bonding pads within the shortest distance between the dies. Besides savings of the manufacturing cost, line crossing generated during packaging can be avoided. The line crossing means the bonding wire going across one of the bonding pads and the corresponding bonding pad also crosses a space over other bonding pads. This causes signal interference between the bonding pads and the bonding wires.

The second bonding wire 100 forms a third bonding point 101 on the bonding pad 70 around the chip area 10a and a fourth bonding point 102 on the first surface 81 of the electronic 80 by the wire bonding. Thus the respective dies 20 (20a, 20b) of the FOWLP unit 1a are electrically connected to the electronic 80, as shown in FIG. 1.

In addition, in order to explain structures and functions of the present invention, in the embodiments shown in FIG. 1, the bonding point around the chip area 10a of the first die 20a and the second die 20b is the third bonding point 101. The bonding point on the first surface 81 of the electronic 80 and close to the chip area 10a of the first die 20a and the second die 20b is the fourth bonding point 102. Take the two second bonding wires 100 as an example, but not use to limit the present invention. Refer to FIG. 1, the first bonding wire 90 and the second bonding wire 100 are formed together by the wire bonding and this helps simplification of the manufacturing process.

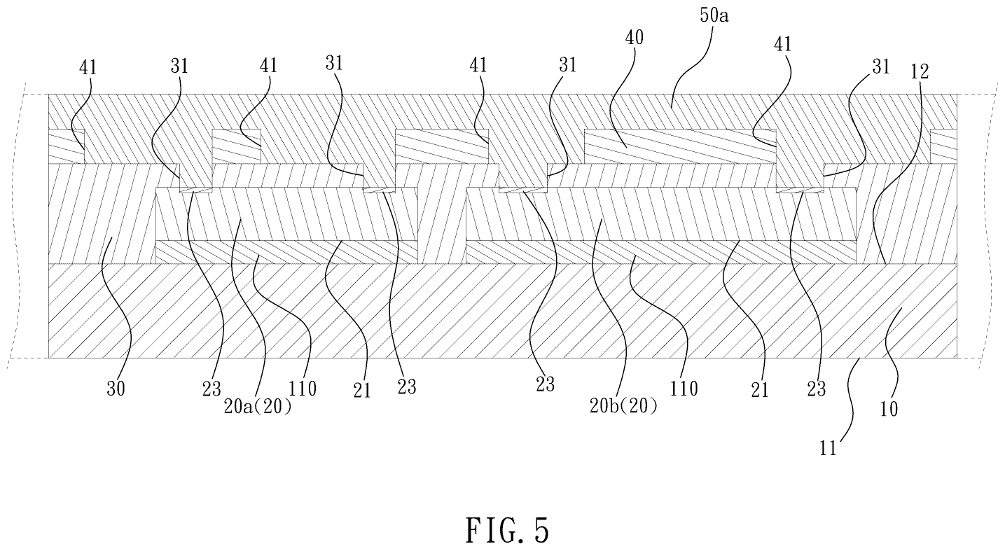

A method of manufacturing the module 1 includes the following steps.
Step S1: providing a substrate 10, as shown in FIG. 2. The substrate 10 includes a first surface 11 and a second surface 12 opposite to the first surface 11, as shown in FIG. 2.
Step S2: arranging a plurality of dies 20 cut from the same wafer or different wafers on the second surface 12 of the substrate 10 in parallel and spaced from one another, as shown in FIG. 2. Each of the dies 20 includes a first surface 21 and a second surface 22 opposite to the first surface 21. The first surface 21 of the die 20 is arranged at the substrate 10 while the second surface 22 of the die 20 is provided with a plurality of die pads 23. An area just above the second surface 22 of the die 20 is defined as a chip area 10a.
Step S3: paving a first dielectric layer 30 over the substrate 10 and the second surface 22 of the respective dies 20, as shown in FIG. 3.
Step S4: forming a plurality of first slots 31 extending horizontally on the first dielectric layer 30 and exposing the respective die pads 21 of the respective dies 20 through the respective first slots 31, as shown in FIG. 3.
Step S5: arranging a second dielectric layer 40 over the first dielectric layer 30, as shown in FIG. 4.
Step S6: forming a plurality of second slots 41 extending horizontally on the second dielectric layer 40 and communicating the second slots 41 with the first slots 31 correspondingly, as shown in FIG. 4.
Step S7: filling a metal paste 50a into the respective first slots 31 and the respective second slots 41 and allowing a level of the metal paste 50a higher than a surface of the second dielectric layer 40, as shown in FIG. 5.
Step S8: grinding the metal paste 50a with the level higher than the surface of the second dielectric layer 40 to make a surface of the metal paste 50a flush with the surface of the second dielectric layer 40 and form a plurality of conductive circuits 50, as shown in FIG. 6.
Step S9: covering the second dielectric layer 40 with an outer protective layer 60, as shown in FIG. 7.
Step S10: forming a plurality of openings 61 on the outer protective layer 60 and at least one of the openings 61 is formed around the chip area 10a on the second surface 22 of the respective dies 20 so that the respective conductive circuits 50 are exposed through the respective openings 61, as shown in FIG. 7.
Step S11: forming a bonding pad 70 in each of the openings 61 of the outer protective layer 60, as shown in FIG. 8. The bonding pad 70 is a metal structure with a certain thickness. The bonding pads 70 are electrically connected to the conductive circuits 50.
Step S12: performing cutting to form a plurality of fan-out wafer-level packaging (FOWLP) units 1a, as shown in FIG. 8. Each of the FOWLP units 1a includes at least two of the dies 20.
Step S13: providing an electronic component 80 with a first surface 81 and disposing the first surface 11 of the substrate 10 of one of the FOWLP units 1a on the first surface 81 of the electronic component 80, as shown in FIG. 1.
Step S14: performing a wire bonding process to make at least one first bonding wire 90 form a first bonding point 91 and a second bonding point 92 on the bonding pads 70 of the dies 20 of the FOWLP unit 1a and make at least two second bonding wires 100 form a third bonding point 101 on the respective bonding pads 70 around the chip area 10a of the FOWLP unit 1a and a fourth bonding point 102 on the electronic component 80, as shown in FIG. 1. The dies 20 in the FOWLP unit 1a on the electronic component 80 are electrically connected through the respective first bonding wires 90. The dies 20 in the FOWLP unit 1a on the electronic component 80 and the electronic component 80 are electrically connected through the respective second bonding wires 100. Thereby the module 1 is formed, as shown in FIG. 1.
The steps S3-S10 of the method of manufacturing the module 1 are considered as key steps of manufacturing the redistribution layer (RDL) of the FOWLP unit 1a. The steps S4-S8 are easy to be implemented precisely so that the manufacturing process is simplified and the respective conductive circuits 50 in the RDL have electrical extension in the XY plane and interconnections. At the same time, the FOWLP unit 1a manufactured still has slim size and light weight to some degree. Even the FOWLP unit 1a includes at least the two dies 20, it's still compact and light weight.

Refer to FIG. 1, a surface of the bonding pad 70 is flush with a surface of the outer protective layer 60 and this helps wire bonding become easier to be performed on the surface of the bonding pad 70 to increase product reliability. Moreover, the bonding pads 70 can withstand a normal force generated during the wire bonding process or formation of the bonding points so that internal circuits will not be damaged due to the normal force. Thereby the internal circuits (such as the conductive circuits 50) are allowed to pass under the bonding pads 70 or arranged under the bonding pads 70.

Refer to FIG. 2, the respective dies 20 have the same specifications, effectiveness, or functions when the dies 20 are cut from the same wafer.

Refer to FIG. 2, when the dies 20 are cut from different wafers, this helps diversified applications of the product. The respective dies 20 have different specifications, effectiveness, or functions. As shown in FIG. 2, the size of the first die 20a is smaller than the size of the second die 20b.

Refer to FIG. 2, levels of the second surfaces 22 of the respective dies on the substrate 10 are the same. Thereby the first slots 31 of the first dielectric layer 30 and the second slots 41 of the second dielectric layer 40 formed by the RDL technique can be extended and formed smoothly and flatly. This helps the following structures stacked over the dies 20 become more flat and even to increase reliability of the product.

Refer to FIG. 2, the first surface 21 of the die 20 is arranged at the substrate 10 by a die attach film (DAF) 110, but not limited.

Compared with the module containing the FOWLP unit available now, the present module 1 has the following advantages.
(1) The steps S3-S10 of the present method of manufacturing the present module 1 are simplified and easily-implemented steps and this is especially helpful in reduction of a thickness of the packaging unit. Thus the manufacturing process of the present invention is simplified. Therefore, production cost is cost and use efficiency and reliability of the module 1 are improved.
(2) The method of forming the conductive circuits 50 in the FOWLP unit 1a of the module 1 according to the present invention can effectively solve the problems of the FOWLP technology available now generated during manufacturing of the respective conductive circuits 50 including higher manufacturing cost and less environmental benefits. The cost for materials and production of the present module 1 can also be reduced.
(3) The present module 1 makes the module products have higher performance (such as the dies 20 with the same specifications, effectiveness, or functions) or more functions (such as the dies 20 with different specifications, effectiveness, or functions). Thereby market competitiveness of the product is improved.

1. A module containing a fan-out wafer-level packaging (FOWLP) unit connected to an electronic by wire bonding comprising:
a substrate provided with a first surface and a second surface opposite to the first surface;
at least two dies cut from the same wafer or different wafers; the dies arranged at the second surface of the substrate in parallel and spaced apart from each other; each of the dies provided with a first surface and a second surface opposite to the first surface; the first surface of the die fixed on the substrate while the second surface of the die provided with a plurality of die pads and an area just above the second surface being defined as a chip area;
a first dielectric layer mounted to the second surface of the substrate and the second surface of the dies; the first dielectric layer provided with a plurality of first slots extending in a horizontal direction; wherein the respective die pads of the dies are exposed through the respective first slots;
a second dielectric layer disposed over the first dielectric layer; second dielectric layer provided with a plurality of second slots extending in a horizontal direction; the respective second slots communicating with the respective first slots;
a plurality of conductive circuits formed by a metal paste filled in the first slots and the second slots; the respective conductive circuits electrically connected to the respective die pads of the respective dies;
an outer protective layer arranged over the second dielectric layer and provided with a plurality of openings; at least two of the openings located around the chip area on the second surface of the respective dies; wherein the respective conductive circuits are exposed through the respective openings;
a plurality of bonding pads which are metal structures with a certain thickness being formed in the respective openings of the outer protective layer and electrically connected to the respective conductive circuits; wherein the dies are electrically connected to the outside through the die pads, the conductive circuits, and the bonding pads located around the chip area on the second surface of the dies in turn to form the fan-out wafer-level packaging (FOWLP) unit;
the electronic having a first surface on which the first surface of the substrate is disposed;
at least one first bonding wire which forms a first bonding point and a second bonding point on the bonding pads of the respective dies by wire bonding so that electrical connections are formed between the respective dies of the FOWLP unit; and
at least two second bonding wire each of which forms a third bonding point on the bonding pads around the chip area and a fourth bonding point on the first surface of the electronic by the wire bonding so that the respective dies of the FOWLP unit are electrically connected to the electronic; wherein the first bonding wire and the second bonding wire are formed together by the wire bonding;
wherein a method of manufacturing the module comprising the steps of:
Step S1: providing a substrate; wherein the substrate is provided with a first surface and a second surface opposite to the first surface;
Step S2: arranging a plurality of dies cut from the same wafer or different wafers on the second surface of the substrate in parallel and spaced from one another; wherein each of the dies includes a first surface and a second surface opposite to the first surface; the first surface of the die is arranged at the substrate while the second surface of the die is provided with a plurality of die pads; an area just above the second surface of the die is defined as a chip area;
Step S3: paving a first dielectric layer over the substrate and the second surface of the respective dies;
Step S4: forming a plurality of first slots extending horizontally on the first dielectric layer and exposing the respective die pads of the respective dies through the respective first slots;
Step S5: paving a second dielectric layer over the first dielectric layer;
Step S6: forming a plurality of second slots extending horizontally on the second dielectric layer and communicating the second slots with the first slots;
Step S7: filling a metal paste into the first slots and the second slots and allowing a level of the metal paste higher than a surface of the second dielectric layer;
Step S8: grinding the metal paste with the level higher than the surface of the second dielectric layer to make a surface of the metal paste flush with the surface of the second dielectric layer and form a plurality of conductive circuits;
Step S9: covering the second dielectric layer with an outer protective layer;
Step S10: forming a plurality of openings on the outer protective layer and at least one of the openings is formed around the chip area on the second surface of the respective dies so that the respective conductive circuits are exposed through the respective openings;
Step S11: forming a bonding pad in each of the openings of the outer protective layer; wherein the bonding pads are metal structures with a certain thickness and electrically connected to the conductive circuits;
Step S12: performing cutting to form a plurality of fan-out wafer-level packaging (FOWLP) units; wherein each of the FOWLP units includes at least two of the dies;
Step S13: providing an electronic which includes a first surface and disposing the first surface of the substrate of one of the FOWLP units on the first surface of the electronic;
Step S14: performing wire bonding to make at least one first bonding wire form a first bonding point and a second bonding point on the respective bonding pads of the respective dies of the FOWLP unit and make at least two second bonding wires form a third bonding point on the respective bonding pads around the chip area of the FOWLP unit and a fourth bonding point on the electronic; wherein the dies in the FOWLP unit on the electronic are electrically connected through the respective first bonding wires; wherein the dies in the FOWLP unit on the electronic are electrically connected to the electronic through the respective second bonding wires; thereby the module is formed.

2. The module as claimed in claim 1, wherein the electronic is a printed circuit board (PCB).

3. The module as claimed in claim 1, wherein a surface of the bonding pad is flush with a surface of the outer protective layer.

4. The module as claimed in claim 1, wherein the dies are cut from the same wafer or different wafers.

5. The module as claimed in claim 1, wherein levels of the second surfaces of the dies on the substrate are the same.

6. The module as claimed in claim 1, wherein the substrate includes a silicon (Si) substrate, a glass substrate, and a ceramic substrate.

7. The module as claimed in claim 1, wherein the metal paste includes silver paste, nano-scale silver paste, copper paste, and nano-scale copper paste.

8. The module as claimed in claim 1, wherein the first surface of the die is disposed on the substrate by a die attach film (DAF).
